(19) United States
(12) Patent Application Publication
(10) Pub. No.: US 2024/0304777 A1
(43) Pub. Date: Sep. 12, 2024

(54) DISPLAY PANEL AND PREPARATION METHOD THEREFOR

(71) Applicant: Chengdu Vistar Optoelectronics Co., Ltd., Chengdu (CN)

(72) Inventors: Yan WANG, Chengdu (CN); Xiuqi HUANG, Chengdu (CN); Fei HUANG, Chengdu (CN); Xiaobiao DONG, Chengdu (CN)

(73) Assignee: Chengdu Vistar Optoelectronics Co., Ltd., Chengdu (CN)

(21) Appl. No.: 18/669,855

(22) Filed: May 21, 2024

Related U.S. Application Data
(63) Continuation of application No. PCT/CN2022/124197, filed on Oct. 9, 2022.

(30) Foreign Application Priority Data
Nov. 30, 2021 (CN) 202111447380.X

(51) Int. Cl. H01L 33/62; H01L 25/16

(52) U.S. Cl. CPC H01L 33/62; H01L 25/167; H01L 2933/0066

(57) ABSTRACT

A display panel and a preparation method therefor are provided. The display panel includes: a driving backplate, a first surface of which is provided with normal bonding areas and redundant bonding areas, at least one of first distances between every two normal bonding areas, which are adjacent to each other is greater than at least one of second distances between each normal bonding area and a corresponding redundant bonding area which is adjacent to the normal bonding area, and at least one normal bonding area and at least one redundant bonding area adjacent thereto constitute a bonding group; and a light emitting layer, located on the first surface and including sub-pixels electrically connected to the normal bonding areas or the redundant bonding areas, and the normal bonding area and the redundant bonding area of the same bonding group are electrically connected to sub-pixels with the same emitting color.

### CROSS REFERENCE TO RELATED APPLICATIONS

The present disclosure is a continuation-application of International (PCT) Patent Application No. PCT/CN2022/124197 filed on filed on Oct. 9, 2022, which claims priority from Chinese patent application No. 202111447380.X filed on Nov. 30, 2021, the entire contents of which are incorporated herein by reference.

### TECHNICAL FIELD

The present disclosure relates to the field of display, and in particular to a display panel and a preparation method of the display panel.

### BACKGROUND

Micro-LED, as a novel display technology, is receiving more and more widespread attention. However, the yield of the mass transfer technology for Micro-LEDs is relatively low at present, and it needs to repair defective pixels after transfer to meet display standards. Due to the tight arrangement of Micro-LEDs, how to improve both the yield of the mass transfer and the yield of repair is an urgent technical problem to be solved.

### SUMMARY OF THE DISCLOSURE

The present disclosure provides a display panel and a preparation method of the display panel.

In one aspect, a technical solution adopted by the present disclosure is to provide a display panel. The display panel includes: a driving backplane, a first surface of the driving backplane is provided with a plurality of normal bonding areas and a plurality of redundant bonding areas; a distance between every two of the plurality of normal bonding areas adjacent to each other is defined as a first distance; a distance between each of the plurality of normal bonding areas and a corresponding one of the redundant bonding areas which is adjacent to the each of the plurality of normal bonding areas is defined as a second distance, and at least one of the first distances is greater than at least one of the second distances; and at least one of the plurality of normal bonding areas and at least one of the plurality of redundant bonding areas adjacent to the at least one of the plurality of normal bonding areas constitute a bonding group; and a light emitting layer, located on the first surface and comprising a plurality of sub-pixels, the plurality of sub-pixels are electrically connected to the normal bonding areas or the redundant bonding areas, and the normal bonding area and the redundant bonding area of the same bonding group are configured to be electrically connected to sub-pixels with the same emitting color.

In another aspect, a technical solution adopted by the present disclosure is to provide a preparation method of a display panel. The method includes: providing a driving backplane; a first surface of the driving backplane is provided with a plurality of normal bonding areas and a plurality of redundant bonding areas; a distance between every two of the plurality of normal bonding areas adjacent to each other is defined as a first distance; a distance between each of the plurality of normal bonding areas and a corresponding one of the redundant bonding areas which is adjacent to the each of the plurality of normal bonding areas is defined as a second distance, and at least one of the first distances is greater than at least one of the second distances; and at least one of the plurality of normal bonding areas and at least one of the plurality of redundant bonding areas adjacent to the at least one of the plurality of normal bonding areas constitute a bonding group; disposing a plurality of sub-pixels in the normal bonding areas of the driving backplane; and introducing a patched sub-pixel with the same emitting color as a defective sub-pixel in the redundant bonding area, in response to the sub-pixel bonded to the normal bonding area of the same bonding group being determined to be the defective sub-pixel.

Different from the related art, the present disclosure may have the following technical effects: on one hand, the driving backplane of the display panel provided by some embodiments of the present disclosure is provided with the plurality of normal bonding areas and the plurality of redundant bonding areas, the normal bonding areas and the redundant bonding areas adjacent to the normal bonding areas may constitute the bonding group. In a practical application process, when the sub-pixel bonded to the normal bonding area is determined to be a defective pixel, a patched sub-pixel with the same emitting color as the defective pixel may be introduced in the redundant bonding area of the same bonding group, increasing the yield of repair compared with in-situ repair. On the other hand, in some embodiments of the present disclosure, at least one of the first distances between every two of the plurality of normal bonding areas, which are adjacent to each other is greater than at least one of the second distances between each of the plurality of normal bonding areas and a corresponding one of the redundant bonding areas which is adjacent to the each of the plurality of normal bonding areas. During the mass transfer process, when the sub-pixels are bonded to the normal bonding areas, the above design may increase a distance between adjacent sub-pixels, reduce interference between adjacent sub-pixels, and reduce probability of rotation and offset of the sub-pixels to improve the yield of transfer. The design may appropriately increase convex areas of transfer heads configured to transfer the sub-pixels, so as to increase tolerances of the offset of the sub-pixels and improve the yield of transfer.

### BRIEF DESCRIPTION OF THE DRAWINGS

In order to more clearly illustrate the technical solutions in the embodiments of the present disclosure, a brief introduction will be provided below for the drawings required in the description of the embodiments. It is apparent that the drawings described herein are merely some embodiments of the present disclosure. For those skilled in the art, other drawings may also be obtained according to the drawings without inventive effort.

FIG. 1 is a schematic structural view of a display panel according to an embodiment of the present disclosure.

FIG. 2 is a partial top view of the display panel shown in FIG. 1 before a defective pixel is repaired according to an embodiment of the present disclosure.

FIG. 3 is a schematic top view of a pixel driving circuit and associated wiring shown in FIG. 2 according to an embodiment of the present disclosure.

FIG. 4 is a partial top view of the display panel shown in FIG. 1 before a defective pixel is repaired according to another embodiment of the present disclosure.

FIG. 5 is a partial top view of the display panel shown in FIG. 1 before a defective pixel is repaired according to another embodiment of the present disclosure.

FIG. 6 is a schematic top view of the pixel driving circuit and associated wiring shown in FIG. 5 according to an embodiment of the present disclosure.

FIG. 7 is a partial top view of the display panel shown in FIG. 1 before a defective pixel is repaired according to another embodiment of the present disclosure.

FIG. 8 is a partial top view of the display panel shown in FIG. 1 before a defective pixel is repaired according to another embodiment of the present disclosure.

FIG. 9 is a partial top view of the display panel shown in FIG. 1 before a defective pixel is repaired according to another embodiment of the present disclosure.

FIG. 10 is a partial top view of the display panel shown in FIG. 1 before a defective pixel is repaired according to another embodiment of the present disclosure.

FIG. 11 is a partial top view of the display panel shown in FIG. 1 before a defective pixel is repaired according to another embodiment of the present disclosure.

FIG. 12 is a partial top view of the display panel shown in FIG. 1 before a defective pixel is repaired according to another embodiment of the present disclosure.

FIG. 13 is a partial top view of the display panel shown in FIG. 1 before a defective pixel is repaired according to another embodiment of the present disclosure.

FIG. 14 is a partial top view of the display panel shown in FIG. 1 before a defective pixel is repaired according to another embodiment of the present disclosure.

FIG. 15 is a schematic flow chart of a preparation method of a display panel according to an embodiment of the present disclosure.

FIG. 16 is a schematic structural view of a display panel shown in FIG. 2 after being repaired according to an embodiment of the present disclosure.

FIG. 17 is a schematic structural view of a display panel shown in FIG. 2 after being repaired according to another embodiment of the present disclosure.

### DETAILED DESCRIPTION

The technical solutions in the embodiments of the present disclosure will be clearly and completely described below in combination with accompanying drawings in the embodiments of the present disclosure. Obviously, the described embodiments are merely parts of the embodiments of the present disclosure, rather than all the embodiments. Based on the embodiments of the present disclosure, any other embodiments obtained by those skilled in the art without inventive effort fall within a protection scope of the present disclosure.

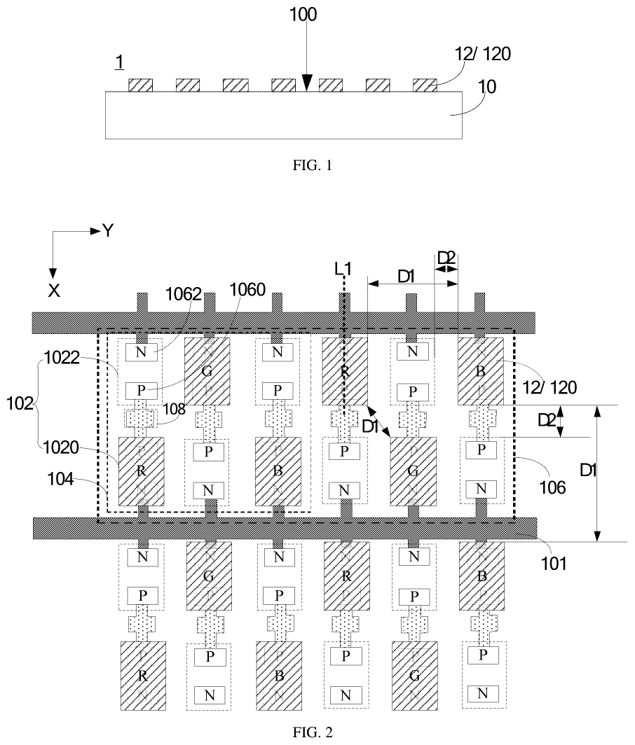

FIG. 1 is a schematic structural view of a display panel according to an embodiment of the present disclosure, and FIG. 2 is a partial top view of the display panel shown in FIG. 1 before a defective pixel is repaired according to an embodiment of the present disclosure. The display panel may be a Micro-LED display panel, etc. The display panel 1 includes a driving backplane 10 and a light emitting layer 12 located on a first surface 100 of the driving backplane 10.

As shown in FIG. 2, the first surface 100 of the driving backplane 10 is provided with a plurality of normal bonding areas 1020 and a plurality of redundant bonding areas 1022. A distance between every two of the plurality of normal bonding areas 1020 adjacent to each other is defined as a first distance D1. A distance between each normal bonding area 1020 and a corresponding one of the redundant bonding areas 1022 which is adjacent to the each normal bonding area 1020 is defined as a second distance D2. At least one of the first distances D1 is greater than at least one of the second distances D2. At least one normal bonding area 1020 and at least one redundant bonding area 1022 adjacent to the at least one normal bonding area 1020 may constitute one bonding group 102. In some embodiments, the first distance D1 may be a distance between edges of the every adjacent two normal bonding areas 1020, and the second distance D2 may be a distance between an edge of each normal bonding area 1020 and an edge of the corresponding redundant bonding area 1022 adjacent to the each normal bonding area 1020. Or, the first distance D1 may be a distance between center points of the every adjacent two normal bonding areas 1020, and the second distance D2 may be a distance between a center point of each normal bonding area 1020 and a center point of the corresponding redundant bonding area 1022 adjacent to the each normal bonding area 1020. In some embodiments, one normal bonding area 1020 and one redundant bonding area 1022 adjacent to the normal bonding area 1020 may constitute one bonding group 102. In other embodiments, one normal bonding area 1020 and a plurality of redundant bonding areas 1022 adjacent to the one normal bonding area 1020 may also constitute one bonding group 102.

The light emitting layer 12 includes a plurality of sub-pixels 120. The sub-pixels 120 may be Micro-LEDs, etc. The sub-pixels 120 may emit red light, green light, or blue light, etc. . . . The sub-pixels 120 are electrically connected to the normal bonding areas 1020 or the redundant bonding areas 1022. The normal bonding area 1020 and the redundant bonding area 1022 of the same bonding group 102 are configured to be electrically connected to sub-pixels 120 with the same emitting color.

In this embodiment, an appearance structure of the normal bonding area 1020 and an appearance structure of the redundant bonding area 1022 may be the same, and a distinguishing standard of the normal bonding area 1020 and the redundant bonding area 1022 is mainly in that priority of the normal bonding area 1020 and priority of the redundant bonding area 1022 are different from each other when the sub-pixels 120 of the light emitting layer 12 are bonded to the normal bonding areas 1020 or the redundant bonding areas 1022. In some embodiments, during the mass transfer process, the sub-pixels 120 are preferentially bonded to the normal bonding areas 1020 of the bonding group 102. When the sub-pixel 120 bonded to the normal bonding area 1020 is determined to be a defective sub-pixel, the defective sub-pixel is removed. Or, the defective sub-pixel is remained or retained when the defective sub-pixel is disconnected, a patched sub-pixel is introduced into the redundant bonding area 1022 of the same bonding group 102, and an emitting color of the patched sub-pixel is the same as an emitting color of the defective sub-pixel when the defective sub-pixel emits light as usual or emits light normally. That is, a bonding time point of the sub-pixel 120 electrically connected to the normal bonding area 1020 is earlier than a bonding time point of the sub-pixel 120 electrically connected to the redundant bonding area 1022, which means the time point for bonding the sub-pixel 120 to the normal bonding area 1020 is earlier than the time point for bonding the sub-pixel 120 to the redundant bonding area 1022. For the same boding group 102, the normal bonding area 1020 is electrically connected to the sub-pixels 120 in preference to or prior to the redundant bonding areas 1022.

In some embodiments, for the same bonding group 102, only one sub-pixel 120 is disposed in the normal bonding area 1020 or the redundant bonding area 1022. Or, for the same bonding group 102, one sub-pixel 120 is disposed in the normal bonding area 1020, another sub-pixel 120 is disposed in the redundant bonding area 1022, the sub-pixel 120 in the normal bonding area 1020 is disconnected from a corresponding pixel driving circuit, and the sub-pixel 120 in the redundant bonding area 1022 is electrically connected to the corresponding pixel driving circuit. Since FIG. 2 is a schematic partial view of the display panel 1 shown in FIG. 1 before the defective pixel is repaired, it may be considered that an area covered by the sub-pixel 120 in FIG. 2 is the normal bonding area 1020, and an area size of the normal bonding area 1020 and an area size of the redundant bonding area 1022 may be the same as an area size of the sub-pixel 120.

In some embodiments, for the display panel 1, a number of the sub-pixels 120 electrically connected to the normal bonding areas 1020 on the display panel 1 is greater than a number of sub-pixels 120 electrically connected to the redundant bonding areas 1022. For example, a ratio of the number of sub-pixels 120 electrically connected to the normal bonding areas 1020 to the number of sub-pixels 120 electrically connected to the redundant bonding areas 1022 may be much greater than 100. In some embodiments, all the sub-pixels 120 are electrically connected to the normal bonding areas 1020. In some embodiments, at least one of the plurality of redundant bonding areas 1022 is not electrically connected to (i.e., disconnected from) the corresponding sub-pixel 120.

On one hand, some embodiments of the present disclosure introduce a redundant repair method, which reduces repair difficulty and increases the yield of repair compared with in-situ repair. On the other hand, in some embodiments of the present disclosure, at least one of the first distances D1 between every two of the plurality of normal bonding areas 1020, which are adjacent to each other, is greater than at least one of the second distances D2 between each normal bonding area 1020 and a corresponding one of the redundant bonding areas 1022 adjacent to the each normal bonding area 1020. During the mass transfer process, when the sub-pixels 120 are bonded to the normal bonding areas 1020, the above design may increase distances between adjacent sub-pixels 120, reduce interference between adjacent sub-pixels 120, and reduce the probability of rotation and offset of the sub-pixels 120, so as to improve the yield of transfer. The design may appropriately increase convex areas of transfer heads configured to transfer the sub-pixels 120, so as to increase tolerances of the offset of the sub-pixels 120 and improve the yield of transfer.

In one embodiment, as shown in FIG. 2, the plurality of normal bonding areas 1020 and the plurality of redundant bonding areas 1022 are arranged in an array along a first direction X and a second direction Y, and the first direction X and the second direction Y are intersected with each other. In some embodiments, the first direction X and the second direction Y are substantially perpendicular to each other. At least one of the first distances D1 between every two of the plurality of normal bonding areas 1020 adjacent to each other in the first direction X is greater than at least one of the second distances D2 between each normal bonding area 1020 and a corresponding one of the redundant bonding areas 1022 adjacent to the each normal bonding area 1020 in the first direction X or the second direction Y. In some embodiments, at least one of the first distances D1 between every two of the plurality of normal bonding areas 1020 adjacent to each other in the second direction Y is greater than at least one of the second distances D2 between each normal bonding area 1020 and a corresponding one of the redundant bonding areas 1022 adjacent to the each normal bonding area 1020 in the first direction X or the second direction Y. In some cases, as shown in FIG. 2, two adjacent normal bonding areas 1020 may also be arranged in an oblique direction, that is, a direction intersected with the first direction X or the second direction Y in FIG. 2. At this time, at least one of the first distances D1 between every two of the plurality of normal bonding areas 1020 adjacent to each other in the oblique direction is still greater than at least one of the second distances D2 between each normal bonding area 1020 and a corresponding one of the redundant bonding areas 1022 adjacent to the each normal bonding area 1020 in the first direction X or the second direction Y. The plurality of normal bonding areas 1020 and the plurality of redundant bonding areas 1022 are arranged in a regular manner, and the producing process is easy to implement. In some embodiments, the emitting colors of the sub-pixels 120 bonded in the two adjacent normal bonding areas 1020 may be the same or different, which is not limited in some embodiments of the present disclosure.

As further shown in FIG. 2, for each of at least one pair of normal bonding areas 1020 adjacent to each other in at least one of the first direction X and the second direction Y, a corresponding one of the redundant bonding areas 1022 is arranged between one of the pair of the normal bonding areas 1020 and the other of the pair of normal bonding areas 1020. This design may increase the first distance D1 between two adjacent normal bonding areas 1020. During the mass transfer process, when the sub-pixels 120 are bonded to the normal bonding areas 1020, the above design may further reduce the interference between the adjacent sub-pixels 120, and reduce the probability of rotation and offset of the sub-pixels 120, so as to improve the yield of transfer. Besides, the design may increase the convex areas of the transfer heads configured to transfer the sub-pixels, so as to increase the tolerances of the offset of the sub-pixels.

As shown in FIG. 2, a plurality of adjacent sub-pixels 120 constitute at least one pixel unit (not labeled), and a plurality of bonding groups 102 electrically connected to the at least one pixel unit constitute at least one combination unit 104. For each combination unit 104, the normal bonding areas 1020 and the redundant bonding areas 1022 of the each combination unit 104 are arranged in two rows in the first direction X, the normal bonding areas 1020 of the each combination unit 104 are alternately arranged in the two rows (i.e., alternately arranged up and down), and the redundant bonding areas 1022 of the each combination unit 104 are alternately arranged in the two rows (i.e., alternately arranged up and down). This design may make the distances between adjacent normal bonding areas 1020 larger. During the mass transfer process, when the sub-pixels 120 are bonded to the normal bonding areas 1020, the above design may further reduce the interference between the adjacent sub-pixels 120, and reduce the probability of rotation and offset of the sub-pixels 120, so as to improve the yield of transfer. Besides, the design may increase the convex areas of the transfer heads configured to transfer the sub-pixels, so as to increase the tolerances of the offset of the sub-pixels.

In some embodiments, as shown in FIG. 2, a number of every two adjacent sub-pixels 120 arranged in the oblique direction is greater than a number of every two adjacent sub-pixels 120 arranged in the same row in the first direction X or the second direction Y. The oblique direction is intersected with the first direction X and the second direction Y. For example, three sub-pixels 120 of one combination unit 104 in FIG. 2 are taken as an example, a red sub-pixel R and a green sub-pixel G are adjacent in a first oblique direction, the green sub-pixel G and a blue sub-pixel B are adjacent in a second oblique direction, and the first oblique direction is different from the second oblique direction, but both the first oblique direction and the second oblique direction are intersected with the first direction X and the second direction Y. The above design may make the distance between two adjacent sub-pixels 120 as large as possible.

In one embodiment, the driving backplane 10 further includes a plurality of pixel driving circuits (not shown), and the normal bonding areas 1020 and the redundant bonding areas 1022 of the same bonding group 102 are electrically connected to the same pixel driving circuit. This design may save wiring spaces of the pixel driving circuits, and be more suitable for high PPI or closely-arranged sub-pixel arrangement scenarios. In some embodiments, structures of the pixel driving circuits may be any one structure in the related art, for example, 2T1C, 7T1C, etc., which is not limited in some embodiments of the present disclosure.

In some embodiments, the sub-pixels 120 may be horizontal light-emitting elements. A side of each sub-pixel 120 facing the first surface 100 is provided with a first electrode (not shown) and a second electrode (not shown). As shown in FIG. 2, each normal bonding area 1020 or redundant bonding area 1022 includes a first electrode bonding area 1060 configured to be electrically connected to the first electrode and a second electrode bonding area 1062 configured to be electrically connected to the second electrode. For example, the first electrode corresponding to the first electrode bonding area 1060 labeled in FIG. 2 is a P-electrode, and the second electrode corresponding to the second electrode bonding area 1062 labeled in FIG. 2 is an N-electrode. In other embodiments, the first electrode corresponding to the first electrode bonding area 1060 may also be the N-electrode, and the second electrode corresponding to the second electrode bonding area 1062 may also be the P-electrode. In some embodiments, two first electrode bonding areas 1060 of the same bonding group 102 are electrically connected to an output terminal of the same pixel driving circuit. That is, the normal bonding areas 1020 and the redundant bonding areas 1022 of the same bonding group 102 are electrically connected to the same pixel driving circuit, and the sub-pixels arranged in the normal bonding areas 1020 and the patched sub-pixels arranged in the redundant bonding areas 1022 may be driven by the same pixel driving circuit. This design may save the wiring spaces of the pixel driving circuits, and be more suitable for high PPI or closely-arranged sub-pixel arrangement scenarios.

In one application scenario, as shown in FIG. 2, the normal bonding areas 1020 and the redundant bonding areas 1022 of the same bonding group 102 are arranged adjacently along the first direction X, and multiple bonding groups 102 of the same combination unit 104 are arranged at intervals along the second direction Y. In the above design, the redundant bonding area 1022 is designed along the first direction X of the normal bonding area 1020, the structural is relatively simple and the producing process is easy to implement.

In some embodiments, as shown in FIG. 2, the plurality of normal bonding areas 1020 and the plurality of redundant bonding areas 1022 arranged in the same row are alternately arranged at intervals in the second direction Y. The normal bonding areas 1020 and the redundant bonding areas 1022 in upper and lower rows in the first direction X are arranged alternately in an opposite manner, and the upper and lower rows are aligned with each other.

On this basis, as shown in FIG. 2, in the first direction X, two first electrode bonding areas 1060 of the same bonding group 102 face each other and are arranged at intervals. The two first electrode bonding areas 1060 of the same bonding group 102 are located between two second electrode bonding areas 1062. That is, in the first direction X, the first electrode bonding areas 1060 and the second electrode bonding areas 1062 of the same bonding group 102 are sequentially arranged at intervals in the following manner: the second electrode bonding area 1062, the first electrode bonding area 1060, the first electrode bonding area 1060, and the second electrode bonding area 1062. In this case, an orthographic projection of the output terminal of the pixel driving circuit projected on the first surface 100 in the first direction X (as shown by a dotted line box labeled 108 in FIG. 2) is located between the two first electrode bonding areas 1060. The above structure is relatively simple and the producing process is easy to implement.

In some embodiments, as shown in FIG. 2 and FIG. 3, FIG. 3 is a schematic top view of a pixel driving circuit and associated wiring shown in FIG. 2 according to an embodiment of the present disclosure. In some embodiments, the driving backplane 10 includes a thin film transistor layer and an insulating layer disposed above the thin film transistor layer. A plurality of pixel driving circuits 103 are located in the thin film transistor layer, and a surface of the insulating layer facing away from the thin film transistor layer forms the first surface 100. The first electrode bonding areas 1060 and the second electrode bonding areas 1062 may be exposed from the first surface 100 of the driving backplane 10 for bonding with the sub-pixels 120. In this case, a position of the insulating layer corresponding to the output terminal of the pixel driving circuit 103 may define a conductive hole (i.e., the position indicated by the dotted line box labeled 108 in FIG. 2 and FIG. 3). The conductive hole is further electrically connected to the two first electrode bonding areas 1060 disposed on opposite sides of the conductive hole through metal wirings. It may be seen from FIG. 2 and FIG. 3 that, the output terminals of the pixel driving circuits 103 are arranged at intervals along the second direction Y, so that the pixel driving circuits 103 may be repeatedly arranged in the second direction Y, thereby reducing the layout difficulty of the pixel driving circuits 103.

As shown in FIG. 2, the pixel unit in FIG. 2 includes three adjacent sub-pixels 120 (a red sub-pixel R, a green sub-pixel G, and a blue sub-pixel B). The combination unit 104 includes three bonding groups 102 electrically connected to the sub-pixels 120 in the corresponding pixel unit. Three normal bonding areas 1020 of the combination unit 104 are arranged alternately up and down, and three redundant bonding areas 1022 of the combination unit 104 are arranged alternately up and down. In some embodiments, the display panel 1 includes multiple repeating units 106. Two adjacent combination units 104 arranged in the second direction Y constitute one repeating unit 106. A plurality of normal bonding areas 1020 of the repeating unit 106 are arranged alternately up and down. A plurality of redundant bonding areas 1022 of the repeating unit 106 are arranged alternately up and down. The design of the repeating units 106 may reduce the complexity for producing the display panel 1.

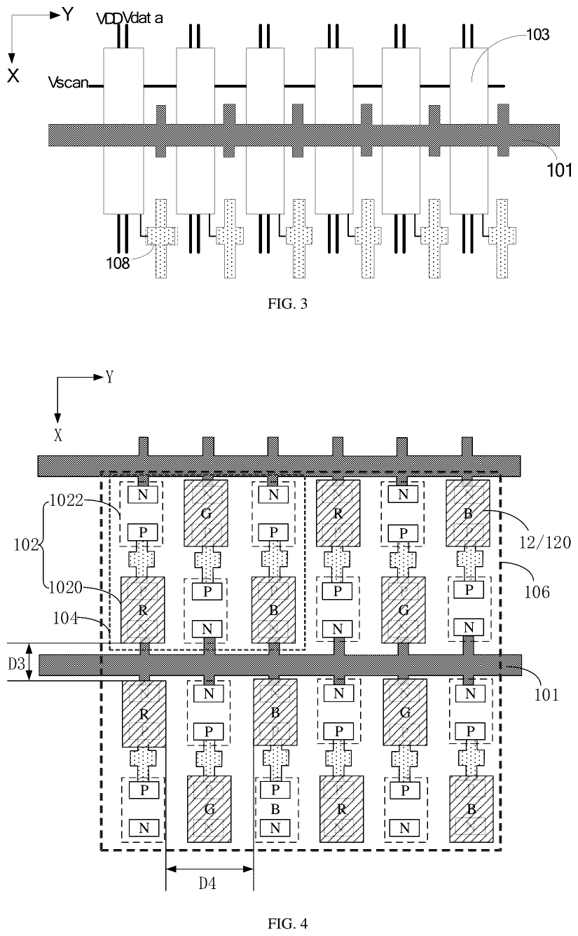

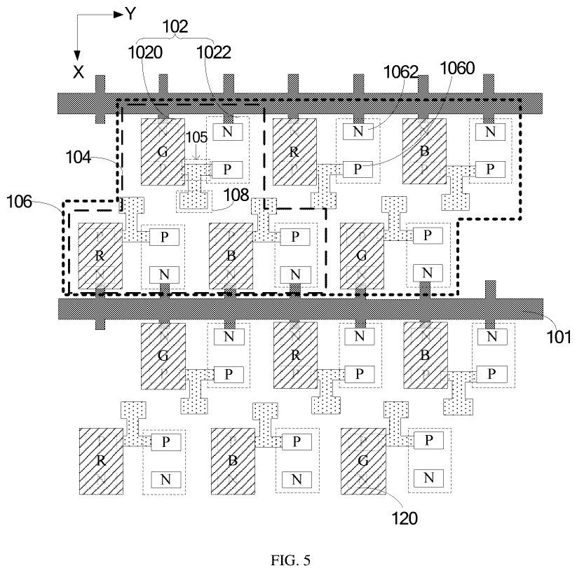

Of course, in other embodiments, the combination units 104 in FIG. 2 may also be arranged in other manner. For example, as shown in FIG. 4, FIG. 4 is a partial top view of the display panel shown in FIG. 1 before a defective pixel is repaired according to another embodiment of the present disclosure. The pixel unit shown in FIG. 4 includes three adjacent sub-pixels 120 (a red sub-pixel R, a green sub-pixel G, and a blue sub-pixel B). The combination unit 104 includes three bonding groups 102 electrically connected to the sub-pixels 120 in the corresponding pixel unit. In the first direction X, the combination units 104 of at least one pair of combination units 104 adjacent to each other are arranged axially symmetrically. At least parts of the normal bonding areas 1020 of two adjacent combination units 104 arranged axially symmetrically, which correspond to the sub-pixels with the same emitting color are arranged adjacent to each other. This design may make parts of the two sub-pixels 120 in the normal bonding areas 1020 in two bonding groups 102 adjacent to each other in the first direction X may be transferred and bonded at the same time or simultaneously, so as to improve the bonding efficiency. Besides, the two sub-pixels will not be affected by the sub-pixels 120 on the remaining normal bonding areas 1020 during the bonding transfer process, so as to improve the yield of bonding. For example, as shown in FIG. 4, two adjacent blue sub-pixels having no redundant bonding area 1022 disposed there between in the first direction X may be transferred and bonded at the same time. The two blue sub-pixels will not be squeezed or collided by adjacent red sub-pixels or green sub-pixels during the bonding process due to the redundant bonding areas 1022 surrounding the two blue sub-pixels.

In some embodiments, as shown in FIG. 4, a third distance D3 between two adjacent normal bonding areas 1020 from two adjacent combination units 104 in the first direction X is shorter than a fourth distance D4 between another two adjacent normal bonding areas 1020 of the same combination unit 104. This design may increase the arrangement density of the pixels to improve the display effect. In some embodiments, the third distance D3 and the fourth distance D4 may be the distance between edges of two adjacent normal bonding areas 1020. Or, the third distance D3 and the fourth distance D4 may be the distance between center points of two adjacent normal bonding areas 1020.

In some embodiments, as shown in FIG. 4, four combination units 104 adjacent to each other in the first direction X and the second direction Y (the four adjacent combination units 104 in the up, down, left, and right directions) constitute one repeating unit 106. The normal bonding areas 1020 and the redundant bonding areas 1022 in the same row of the repeating unit 106 are arranged alternately in the second direction Y. This design may reduce the difficulty of producing process.

In another application scenario, as shown in FIG. 5, FIG. 5 is a partial top view of the display panel shown in FIG. 1 before a defective pixel is repaired according to another embodiment of the present disclosure. The normal bonding areas 1020 and the redundant bonding areas 1022 of the same bonding group 102 are arranged at intervals along the second direction Y. Multiple bonding groups 102 of the same combination unit 104 are arranged in two rows along the first direction X, and the bonding groups 102 in the two rows are staggered or misaligned or offset from each other. In some embodiments, the amount of misalignment or offset between the bonding groups 102 in the two rows is one redundant bonding area 1022 or one normal bonding area 1020. In the above design, the redundant bonding area 1022 is designed along the second direction Y of the normal bonding area 1020, the structure is relatively simple and the producing process is easy to implement.

In some embodiments, as shown in FIG. 5, the plurality of normal bonding areas 1020 and the plurality of redundant bonding areas 1022 arranged in the same row are alternately arranged at intervals in the second direction Y. The normal bonding areas 1020 and the redundant bonding areas 1022 in upper and lower rows are arranged alternately in the first direction X in the same manner, and the normal bonding areas 1020 and the redundant bonding areas 1022 in the upper and lower rows are staggered or offset from each other.

On this basis, as shown in FIG. 5, in the second direction Y, the two first electrode bonding areas 1060 of the same bonding group 102 face each other and are arranged at intervals, and the two second electrode bonding areas 1062 of the same bonding group 102 face each other and are arranged at intervals. A gap is defined between two rows of the bonding groups 102 of the same combination unit 104. The orthographic projection of the output terminal of the pixel driving circuit 103 projected on the first surface 100 (as shown in the dotted box labeled 108 in FIG. 5) is located in the gap and between two first electrode bonding areas 1060 of the same bonding group 102. This design may reduce the difficulty of wiring and producing process. In some embodiments, as shown in FIG. 5, in the second direction Y, an intermediate region 105 is defined between the two first electrode bonding areas 1060 of the same bonding group 102. The orthographic projection of the output terminal of the pixel driving circuit 103 projected on the first surface 100 (as shown in the dotted box labeled 108 in FIG. 5) and the intermediate region 105 are arranged at intervals in the first direction X.

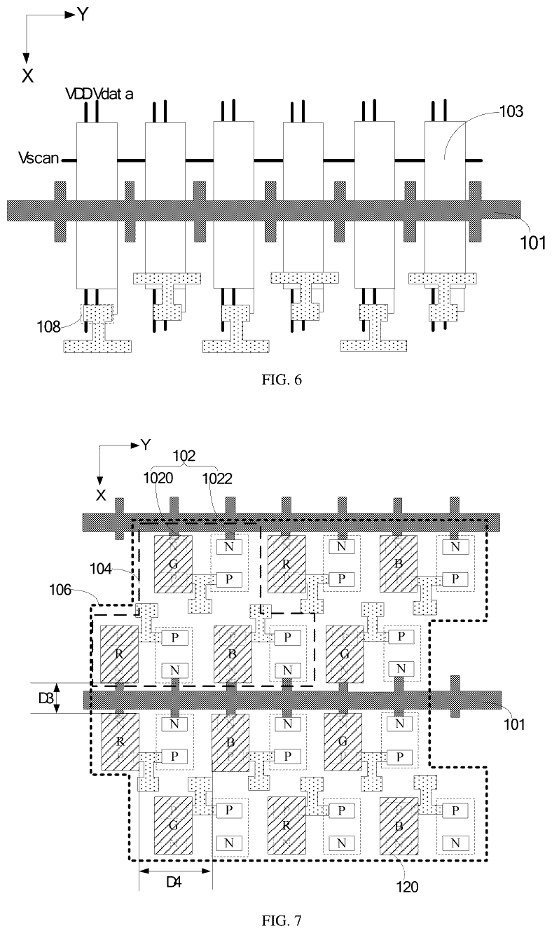

In some embodiments, as shown in FIG. 5 and FIG. 6, FIG. 6 is a schematic top view of the pixel driving circuit and associated wiring shown in FIG. 5 according to an embodiment of the present disclosure. In some embodiments, the driving backplane 10 includes a thin film transistor layer and an insulating layer disposed above the thin film transistor layer. The pixel driving circuits 103 are located in the thin film transistor layer, and a surface of the insulating layer facing away from the thin film transistor layer forms the first surface 100. The first electrode bonding areas 1060 and the second electrode bonding areas 1062 may be exposed from the first surface 100 of the driving backplane 10 for bonding with the sub-pixels 120. In this case, a position of the insulating layer corresponding to the output terminal of the pixel driving circuit 103 may define a conductive hole (i.e., the position indicated by the dotted line box labeled 108 in FIG. 5 and FIG. 6). The conductive hole is further electrically connected to the two first electrodes bonding area 1060 on opposite sides of the conductive hole through the metal wirings. It may be seen from FIG. 5 and FIG. 6 that, the output terminals of the pixel driving circuits 103 are arranged at intervals along the second direction Y, so that the pixel driving circuits 103 may be repeatedly arranged in the second direction Y, thereby reducing the layout difficulty of the pixel driving circuits 103.

As shown in FIG. 5, the pixel unit in FIG. 5 includes three adjacent sub-pixels 120 (a red sub-pixel R, a green sub-pixel G, and a blue sub-pixel B). The combination unit 104 includes three bonding groups 102 electrically connected to the sub-pixels 120 in the corresponding pixel unit. Three normal bonding areas 1020 of the combination unit 104 are arranged alternately up and down, and three redundant bonding areas 1022 of the combination unit 104 are arranged alternately up and down. In some embodiments, the display panel 1 includes multiple repeating units 106. In the second direction Y, two adjacent combination units 104 constitute one repeating unit 106. A plurality of normal bonding areas 1020 of the repeating unit 106 are arranged alternately up and down. A plurality of redundant bonding areas 1022 of the repeating unit 106 are arranged alternately up and down. The design of the repeating units 106 may reduce the complexity for producing the display panel 1.

Of course, in other embodiments, the combination units 104 in FIG. 5 may also be arranged in other manner. For example, as shown in FIG. 7, FIG. 7 is a partial top view of the display panel shown in FIG. 1 before a defective pixel is repaired according to another embodiment of the present disclosure. The pixel unit shown in FIG. 7 includes three adjacent sub-pixels 120 (a red sub-pixel R, a green sub-pixel G, and a blue sub-pixel B). The combination unit 104 includes three bonding groups 102 electrically connected to the sub-pixels 120 in the corresponding pixel unit. In the first direction X, the combination units 104 of at least one pair of combination units 104 adjacent to each other are arranged axially symmetrically. At least parts of the normal bonding areas 1020, which correspond to the sub-pixels with the same emitting color, of two adjacent combination units 104 arranged axially symmetrically, are arranged adjacent to each other. This design may make parts of the two sub-pixels 120 in the normal bonding areas 1020 in two bonding groups 102 adjacent to each other in the first direction X may be transferred and bonded at the same time or simultaneously, so as to improve the bonding efficiency. Besides, the two sub-pixels will not be affected by the sub-pixels 120 on the remaining normal bonding areas 1020 during the bonding transfer process, so as to improve the yield of bonding. For example, as shown in FIG. 7, two adjacent blue sub-pixels having no redundant bonding area 1022 disposed there between in the first direction X may be transferred and bonded at the same time. The two blue sub-pixels will not be squeezed or collided by adjacent red sub-pixels or green sub-pixels during the bonding process due to the redundant bonding areas 1022 surrounding the two blue sub-pixels.

In some embodiments, as shown in FIG. 7, a third distance D3 between two adjacent normal bonding areas 1020 from two adjacent combination units 104 in the first direction X is shorter than a fourth distance D4 between another two adjacent normal bonding areas 1020 of the same combination unit 104. This design may increase the arrangement density of the pixels to improve the display effect. In some embodiments, the third distance D3 and the fourth distance D4 may be the distance between edges of two adjacent normal bonding areas 1020. Or, the third distance D3 and the fourth distance D4 may be the distance between center points of two adjacent normal bonding areas 1020.

In some embodiments, as shown in FIG. 7, the display panel 1 includes a plurality of repeating units 106, and four combination units 104 adjacent to each other in the first direction X and the second direction Y (the four adjacent combination units 104 in the up, down, left, and right directions) constitute one repeating unit 106. The normal bonding areas 1020 and the redundant bonding areas 1022 in the same row of the repeating unit 106 are arranged alternately in the second direction Y. This design may reduce the difficulty of producing process.

In the above embodiments, the normal bonding areas 1020 and the redundant bonding areas 1022 of the same combination unit 104 are arranged alternately up and down. In other embodiments, the normal bonding areas 1020 may be arranged in a row and the redundant bonding areas 1022 of the same combination unit 104 may be arranged in another row.

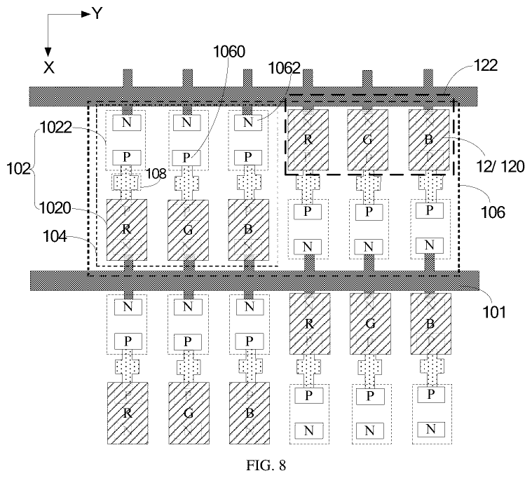

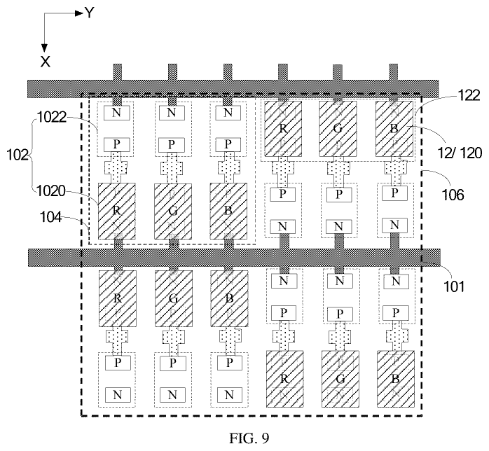

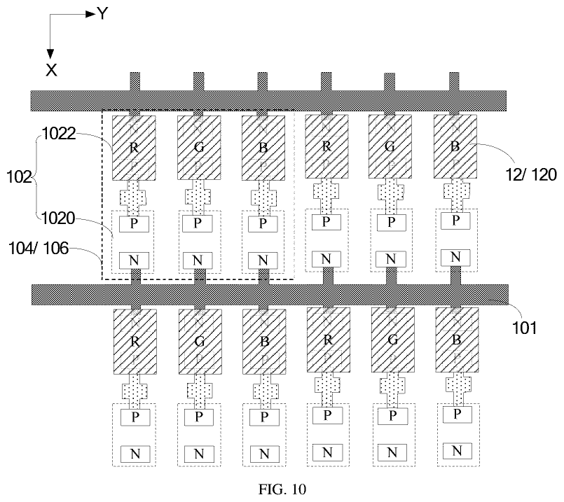

In an application scenario, as shown in FIG. 8, FIG. 8 is a partial top view of the display panel shown in FIG. 1 before a defective pixel is repaired according to another embodiment of the present disclosure. A plurality of adjacent sub-pixels 120 constitute one pixel unit 122, and a plurality of bonding groups 102 electrically connected to the pixel unit 122 constitute one combination unit 104. The normal bonding areas 1020 and the redundant bonding areas 1022 of the same bonding group 102 are arranged along the first direction X. A plurality of normal bonding areas 1020 of the combination unit 104 are adjacently arranged in the same row along the second direction Y. A plurality of redundant bonding areas 1022 of the combination unit 104 are adjacently arranged in another same row along the second direction Y. A row of redundant bonding areas 1022 is provided between two rows of normal bonding areas 1020 of two adjacent combination units 104 in each of the first direction X and the second direction Y. The structural is relatively simple and the producing process is easy to implement. The transfer head may pick up three sub-pixels 120 bonded to the same combination unit 104 at the same time or simultaneously during the process of bonding the sub-pixels 120 to the normal bonding area 1020, so as to improve the bonding efficiency.

On this basis, as shown in FIG. 8, the driving backplane 10 includes a plurality of pixel driving circuits 103, and the normal bonding area 1020 and the redundant bonding area 1022 of the same bonding group 102 may be electrically connected to output terminals of the same pixel driving circuit 103. In some embodiments, in the first direction X, two first electrode bonding areas 1060 of the same bonding group 102 face each other and are arranged at intervals. The two first electrode bonding areas 1060 of the same bonding group 102 are located between two second electrode bonding areas 1062. That is, in the first direction X, the first electrode bonding areas 1060 and the second electrode bonding areas 1062 of the same bonding group 102 are sequentially arranged at intervals in the following manner: the second electrode bonding area 1062, the first electrode bonding area 1060, the first electrode bonding area 1060, and the second electrode bonding area 1062. In this case, an orthographic projection of the output terminal of the pixel driving circuit 103 projected on the first surface 100 in the first direction X (as shown by the dotted box labeled 108 in FIG. 8) is located between the two first electrode bonding areas 1060. The above structure is relatively simple and the producing process is easy to implement. In this case, the corresponding pixel driving circuit 103 and associated wiring in FIG. 8 may be depicted as shown in FIG. 3.

In addition, the pixel unit 122 in FIG. 8 includes three adjacent sub-pixels 120 (a red sub-pixel R, a green sub-pixel G, and a blue sub-pixel B). The combination unit 104 includes three bonding groups 102 electrically connected to sub-pixels 120 in the corresponding pixel unit 122. Three normal bonding areas 1020 of the combination unit 104 are arranged in the same row. Three redundant bonding areas 1022 of the combination unit 104 are arranged in another same row. The display panel includes multiple repeating units 106. In the second direction Y, two adjacent combination units 104 constitute one repeating unit 106, and two rows of the normal bonding areas 1020 of two combination units 104 of the repeating unit 106 are arranged alternately up and down. The design of the repeating unit 106 may reduce the complexity for producing the display panel.

In some embodiments, as shown in FIG. 8, a number of every two adjacent pixel units 122 arranged in the oblique direction is greater than a number of every two adjacent pixel units 122 arranged in the same row in the first direction X or the second direction Y. The oblique direction is intersected with the first direction X and the second direction Y. All the sub-pixels 120 in each pixel unit 122 in two adjacent pixel units 122 are arranged in the same row along the first direction X or the second direction Y. The sub-pixels 120 in a certain pixel unit 122 which not arranged in the same row are not included in a counting range. For example, taking FIG. 8 as an example, a pixel unit 122 corresponding to the combination unit 104 in an upper left corner is adjacent to a pixel unit 122 corresponding to the combination unit 104 in an upper right corner in the first oblique direction, and the pixel unit 122 corresponding to the combination unit 104 in the upper left corner is adjacent to a pixel unit 122 corresponding to the combination unit 104 in a lower right corner in the second oblique direction. The first oblique direction is different from the second oblique direction, but both the first oblique direction and the second oblique direction are intersected with the first direction X and the second direction Y. The above design may make the distance between two adjacent pixel units 122 as large as possible.

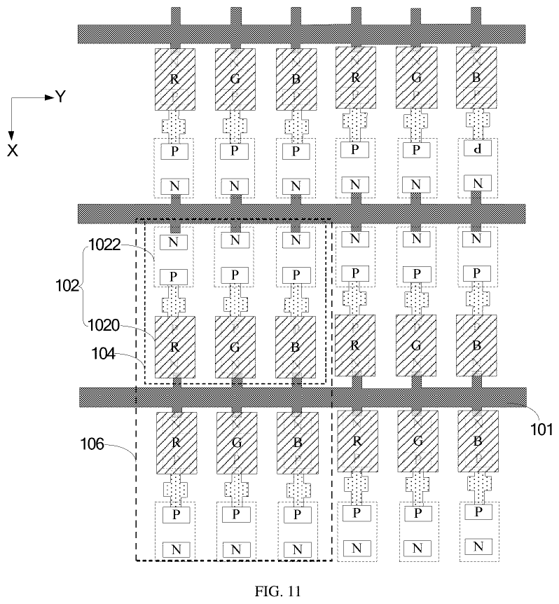

Of course, in other embodiments, the combination units 104 in FIG. 8 may also be arranged in other manner. For example, as shown in FIG. 9, FIG. 9 is a partial top view of the display panel shown in FIG. 1 before a defective pixel is repaired according to another embodiment of the present disclosure. The pixel unit 122 in FIG. 9 includes three adjacent sub-pixels 120 (a red sub-pixel R, a green sub-pixel G and a blue sub-pixel B). The combination unit 104 includes three bonding groups 102 electrically connected to the sub-pixels 120 in the pixel unit 122. Three normal bonding areas 1020 of the combination unit 104 are arranged in the same row, and three redundant bonding areas 1022 of the combination unit 104 are arranged in another same row. In the first direction X, the combination units 104 of at least one pair of combination units 104 adjacent to each other are arranged axially symmetrically. The normal bonding areas 1020, which correspond to the sub-pixels with the same emitting color, of two adjacent combination units 104 arranged axially symmetrically, face each other.

In some embodiments, as shown in FIG. 9, the display panel 1 includes a plurality of repeating units 106, and four combination units 104 adjacent to each other in the first direction X and the second direction Y (the four adjacent combination units 104 in the up, down, left, and right directions) constitute one repeating unit 106. In the second direction Y, the arrangement of the redundant bonding areas 1022 and the normal bonding areas 1020 in two adjacent combination units 104 of the repeating unit 106 is reversed. This design may reduce the difficulty of the producing process. In another application scenario, as shown in FIG. 10, FIG. 10 is a partial top view of the display panel shown in FIG. 1 before a defective pixel is repaired according to another embodiment of the present disclosure. The difference between the embodiment shown in FIG. 10 and the embodiment shown in FIG. 8 is that a row of redundant bonding areas 1022 is provided between two rows of normal bonding areas 1020 of two adjacent combination units 104 in the first direction X, and two rows of normal bonding areas 1020 of two adjacent combination units 104 in the direction Y are arranged adjacently, that is, on the same straight line. The structural is relatively simple and the producing process is easy to realize.

In addition, the pixel unit 122 in FIG. 10 includes three adjacent sub-pixels 120 (a red sub-pixel R, a green sub-pixel G, and a blue sub-pixel B). The combination unit 104 includes three bonding groups 102 electrically connected to sub-pixels 120 in the corresponding pixel unit 122. In this case, one combination unit 104 constitutes one repeating unit 106. The design of the repeating unit 106 may reduce the complexity for producing the display panel.

Of course, in other embodiments, the combination units 104 in FIG. 10 may also be arranged in other manner. For example, as shown in FIG. 11, FIG. 11 is a partial top view of the display panel shown in FIG. 1 before a defective pixel is repaired according to another embodiment of the present disclosure. In the first direction X, the combination units 104 of at least one pair of combination units 104 adjacent to each other are arranged axially symmetrically. The normal bonding areas 1020 of two adjacent combination units 104 arranged axially symmetrically, which correspond to the sub-pixels 120 with the same emitting color, are arranged adjacent to each other. Further, the display panel 1 includes a plurality of repeating units 106, and two adjacent combination units 104 arranged in the first direction X constitute one repeating unit 106.

As shown in FIG. 2, FIG. 4, FIG. 5, FIG. 7, or FIG. 8, the second electrode bonding areas 1062 of all the normal bonding areas 1020 and the redundant bonding areas 1022 in the same row in the second direction Y are located on the same straight line, and all the second electrode bonding areas 1062 on the same straight line are electrically connected to a same power supply voltage line 101. This design may save wiring areas of the pixel driving circuits 103, and is suitable for high PPI or closely-arranged display pixel arrangement scenarios.

In some embodiments, as shown in FIG. 2, FIG. 4, FIG. 5, FIG. 7, or FIG. 8, the power supply voltage line 101 is located between two rows of the second electrode bonding areas 1062 in the first direction X, and the power supply voltage line 101 is electrically connected to the two rows of the second electrode bonding areas 1062 adjacent to the power supply voltage line 101. This design may further save the wiring areas of the pixel driving circuits 103, and is suitable for high PPI or closely-arranged display pixel arrangement scenarios.

In some embodiments, as shown in FIG. 2, FIG. 4, FIG. 5, FIG. 7, or FIG. 8, the power supply voltage line 101 may provide a VSS low power supply voltage when the second electrode bonding areas 1062 electrically connected to the power supply voltage line 101 are configured to be bonded to N-electrodes. Of course, the power supply voltage line 101 may provide a VDD high power supply voltage when the second electrode bonding areas 1062 electrically connected to the power supply voltage line 101 are configured to be bonded to P-electrodes, which are not limited in some embodiments of the present disclosure.

In addition, as shown in FIG. 2, each sub-pixel 120 defines a first axis of symmetry L1. An extension direction of the first axis of symmetry L1 is substantially parallel to the first direction X. In other embodiments, the extending direction of the first axis of symmetry L1 of the sub-pixel 120 may also be intersected with the first direction X, and an intersection angle between the extending direction of the first axis of symmetry L1 and the first direction X may be approximately 30 degrees, approximately 45 degrees, or approximately 90 degrees.

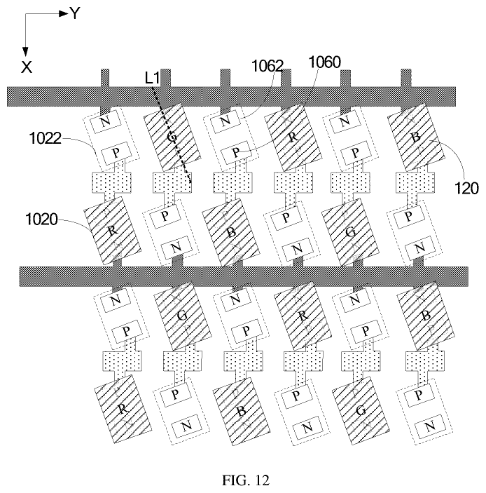

For example, as shown in FIG. 12, FIG. 12 is a partial top view of the display panel shown in FIG. 1 before a defective pixel is repaired according to another embodiment of the present disclosure. As shown in FIG. 12, the first axis of symmetry L1 of each sub-pixel 120 is intersected with the first direction X, and the first axis of symmetry L1 of all the sub-pixels 120 are arranged substantially parallel to each other. In this case, positions of the first electrode bonding areas 1060 and the second electrode bonding areas 1062 in the redundant bonding areas 1022 and the normal bonding areas 1020 shown in FIG. 2 will be rotated to positions in FIG. 10 in accordance with positions of the sub-pixels 120. The above design is relatively simple and easy to be implemented.

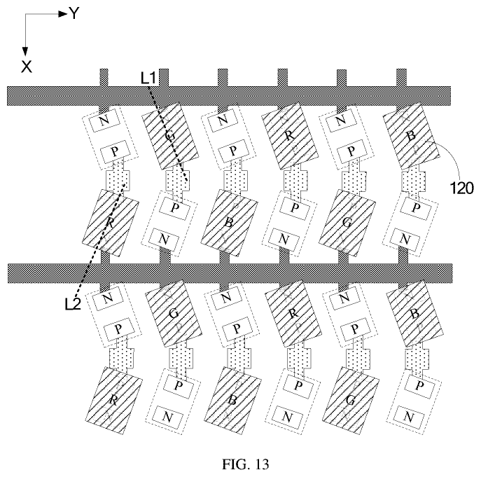

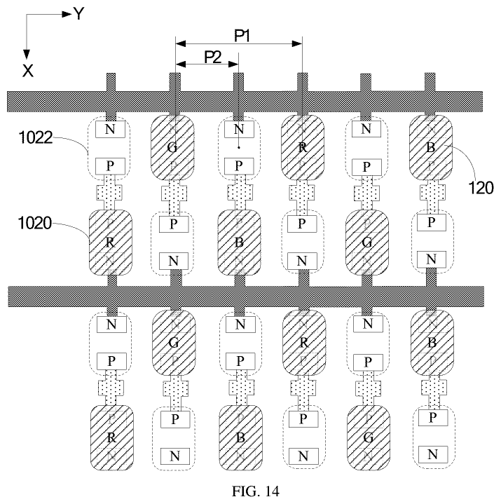

For another example, as shown in FIG. 13, FIG. 13 is a partial top view of the display panel shown in FIG. 1 before a defective pixel is repaired according to another embodiment of the present disclosure. As shown in FIG. 13, the first axis of symmetry L1 of each sub-pixel 120 is intersected with the first direction X, and the extending direction of the first axis of symmetry L1 of each of a first row of sub-pixels 120 is intersected with an extending direction of the first axis of symmetry L1 of each of a second row of sub-pixels 120 adjacent to the first row in the first direction X. In some embodiments, an intersection angle between the first direction X and the extending direction of the first symmetry axis L1 of each of the first row of sub-pixels 120 is substantially equal to an intersection angle between the first direction X and the extending direction of the first symmetry axis L1 of each of the second row of sub-pixels 120 adjacent to the first row in the first direction X. The above design is relatively simple and easy to implement.

As shown in FIG. 2, the orthographic projection of each sub-pixel 120 projected on the first surface is substantially in shape of a rectangle. Or, as shown in FIG. 14, FIG. 14 is a partial top view of the display panel shown in FIG. 1 before a defective pixel is repaired according to another embodiment of the present disclosure. The orthographic projection of each sub-pixel 120 projected on the first surface is substantially in shape of a rounded rectangle. In other embodiments, the orthographic projection of each sub-pixel 120 projected on the first surface may also be a circular, elliptical, triangular, trapezoidal, pentagonal, hexagonal, or other special-shaped structures, which is not limited herein. The sub-pixels 120 of the above shape are easy to produce. As shown in FIG. 14, a distance P1 between the center points of the sub-pixels 120 in the two adjacent normal bonding areas 1020 is greater than a distance P2 between the center point of the sub-pixel 120 in the normal bonding area 1020 and the center point of the sub-pixel 120 in the redundant bonding area 1022 adjacent to the normal bonding areas 1020.

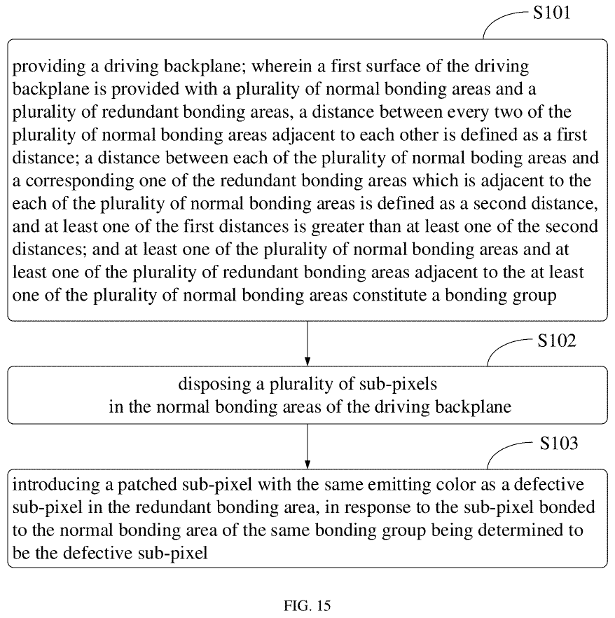

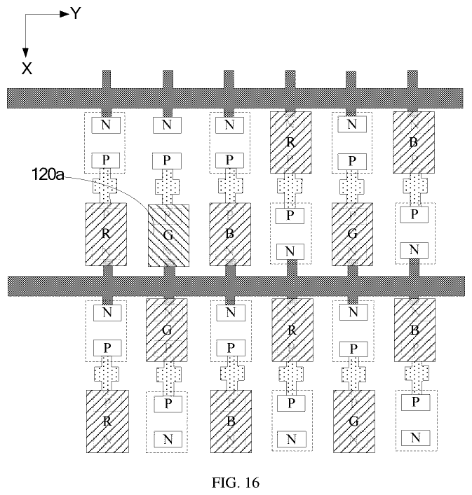

As shown in FIG. 15, FIG. 15 is a schematic flow chart of a preparation method of a display panel according to an embodiment of the present disclosure. The preparation method may include operations executed by the following blocks.

At block 101, a driving backplane is provided. A first surface of the driving backplane is provided with a plurality of normal bonding areas and a plurality of redundant bonding areas. A distance between every two of the plurality of normal bonding areas, which are adjacent to each other, is defined as a first distance. A distance between each normal bonding area and a corresponding one of the redundant bonding areas, which is adjacent to the each normal bonding area, is defined as a second distance. At least one of the first distances is greater than at least one of the second distances. At least one of the plurality of normal bonding areas and at least one of the plurality of redundant bonding areas adjacent to the at least one of the plurality of normal bonding areas constitute one bonding group.

In some embodiments, the structure of the driving backplane may refer to any of the foregoing embodiments, and details are not repeated here.

At block 102, a plurality of sub-pixels are disposed in the normal bonding areas of the driving backplane.

In some embodiments, a plurality of sub-pixels may be simultaneously transferred to the normal bonding areas at corresponding positions by a mass transfer device, and the sub-pixels may be bonded and connected to the normal bonding areas by substances such as solder. In some embodiments, the diagram corresponding to the block 102 may refer to FIG. 2.

At block 103, a patched sub-pixel with the same emitting color as a defective sub-pixel is introduced on or bonded to the redundant bonding area, in response to the sub-pixel bonded to the normal bonding area of the same bonding group being determined to be the defective sub-pixel.

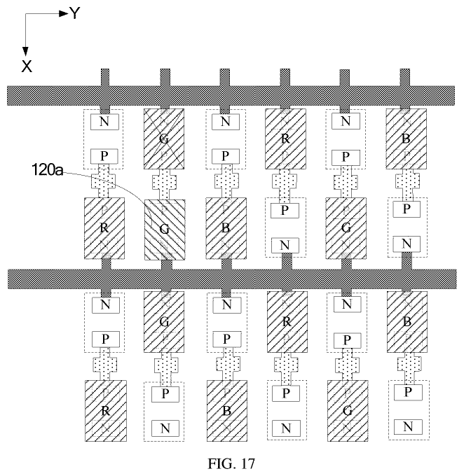

In some embodiments, after the block 102, a lighting test may be performed on the sub-pixels in the normal bonding areas by the driving backplane. If the brightness of one sub-pixel is abnormal (including the situations that the brightness is lower than a first threshold or the brightness exceeds a second threshold), the sub-pixel is determined as a defective sub-pixel. The defective sub-pixel may be removed from the normal bonding area by means of laser, etc., and the patched sub-pixel with the same emitting color may be provided in the redundant bonding area of the same bonding group to replace the sub-pixel in the original normal bonding area. For example, as shown in FIG. 16, FIG. 16 is a schematic structural view of a display panel shown in FIG. 2 after being repaired according to an embodiment of the present disclosure. Assuming that a green sub-pixel G in an upper left portion of FIG. 2 is found to be a defective sub-pixel after the lighting test, after the defective sub-pixel is removed, a patched sub-pixel 120a is introduced in or bonded to the corresponding redundant bonding area, and the patched sub-pixel 120a may emit green light.

Or, if the defective sub-pixel is a disconnected sub-pixel, the defective sub-pixel may be reserved, and the patched sub-pixel with the same emitting color may be arranged in the redundant bonding area of the same bonding group to replace the defective sub-pixel in the normal bonding area. For example, as shown in FIG. 17, FIG. 17 is a schematic structural view of a display panel shown in FIG. 2 after being repaired according to another embodiment of the present disclosure. Assuming that the green sub-pixel G in the upper left portion of FIG. 2 is found to be a defective sub-pixel after the lighting test and the defective sub-pixel is a disconnected sub-pixel and cannot emit green light normally, the defective sub-pixel is reserved, a patched sub-pixel 120a is introduced in or bonded to the corresponding redundant bonding area, and the patched sub-pixel 120a may emit green light.

The above description is only embodiments of the present disclosure, and does not limit the scope of the present disclosure. Any equivalent structural transformations or equivalent process transformations made by using the specification and the drawings of the present disclosure, or directly or indirectly apply the specification and the drawings of the present disclosure to other related technical fields, are all included within the protection scope of the present disclosure.

What is claimed is:

1. A display panel, comprising:
a driving backplane, wherein a first surface of the driving backplane is provided with a plurality of normal bonding areas and a plurality of redundant bonding areas; a distance between every two of the plurality of normal bonding areas adjacent to each other is defined as a first distance, a distance between each of the plurality of normal bonding areas and a corresponding one of the redundant bonding areas which is adjacent to the each of the plurality of normal bonding areas is defined as a second distance, and at least one of the first distances is greater than at least one of the second distances; and at least one of the plurality of normal bonding areas and at least one of the plurality of redundant bonding areas adjacent to the at least one of the plurality of normal bonding areas constitute a bonding group; and
a light emitting layer, located on the first surface and comprising a plurality of sub-pixels, wherein the plurality of sub-pixels are electrically connected to the normal bonding areas or the redundant bonding areas, and the normal bonding area and the redundant bonding area of the same bonding group are configured to be electrically connected to sub-pixels with the same emitting color.

2. The display panel according to claim 1, wherein the display panel satisfies at least one of:
at least one of the plurality of redundant bonding areas is disconnected from the sub-pixel;
for the same bonding group, the normal bonding areas are electrically connected to the sub-pixels in preference to the redundant bonding areas;
a number of sub-pixels electrically connected to the plurality of normal bonding areas is greater than a number of sub-pixels electrically connected to the plurality of redundant bonding areas; and
all the plurality of sub-pixels are electrically connected to the plurality of normal bonding areas.

3. The display panel according to claim 1, wherein the plurality of normal bonding areas and the plurality of redundant bonding areas are arranged in an array along a first direction and a second direction, and the first direction and the second direction are intersected with each other; and
wherein the display panel satisfies at least one of:
at least one of the first distances between every two of the plurality of normal bonding areas adjacent to each other in the first direction is greater than at least one of the second distances between each of the plurality of normal bonding area and a corresponding one of the redundant bonding areas adjacent to the each of the plurality of normal bonding area in the first direction or the second direction; and
at least one of the first distances between every two of the plurality of normal bonding areas adjacent to each other in the second direction is greater than at least one of the second distances between each of the plurality of normal bonding area and a corresponding one of the redundant bonding areas adjacent to the each of the plurality of normal bonding area in the first direction or the second direction.

4. The display panel according to claim 3, wherein for each of at least one pair of normal bonding areas adjacent to each other in at least one of the first direction and the second direction, a corresponding one of the redundant bonding areas is arranged therebetween.

5. The display panel according to claim 1, wherein the plurality of normal bonding areas and the plurality of redundant bonding areas are arranged in an array along a first direction and a second direction, and the first direction and the second direction are intersected with each other; a plurality of adjacent sub-pixels constitute a pixel unit, and a plurality of bonding groups electrically connected to the pixel unit constitute a combination unit; and
wherein the plurality of normal bonding areas and the plurality of redundant bonding areas of the combination unit are arranged in two rows in the first direction, the plurality of normal bonding areas of the combination unit are alternately arranged in the two rows, and the plurality of redundant bonding areas of the combination unit are alternately arranged in the two rows.

6. The display panel according to claim 5, wherein a number of adjacent sub-pixels arranged in an oblique direction is greater than a number of adjacent sub-pixels arranged in the same row in the first direction or the second direction, and the oblique direction is intersected with the first direction and the second direction.

7. The display panel according to claim 5, wherein the normal bonding areas and the redundant bonding areas of the same bonding group are arranged along the first direction, and the plurality of bonding groups of the same combination unit are arranged at intervals along the second direction.

8. The display panel according to claim 5, wherein the normal bonding areas and the redundant bonding areas of the same bonding group are arranged at intervals along the second direction, the plurality of bonding groups of the same combination unit are arranged in two rows along the first direction, and the plurality of bonding groups in the two rows are staggered from each other.

9. The display panel according to claim 7, wherein the pixel unit comprises three sub-pixels, the combination unit comprises three bonding groups; two adjacent combination units arranged in the second direction constitute a repeating unit; the plurality of normal bonding areas of the repeating unit are alternately arranged up and down, and the plurality of redundant bonding areas of the repeating unit are alternately arranged up and down.

10. The display panel according to claim 7, wherein the pixel unit comprises three sub-pixels, the combination unit comprises three bonding groups; in the first direction, the combination units of at least one pair of combination units adjacent to each other are arranged axially symmetrically, and at least parts of the plurality of normal bonding areas of two adjacent combination units arranged axially symmetrically, which correspond to the sub-pixels with the same emitting color are arranged adjacent to each other.

11. The display panel according to claim 7, wherein a third distance between each of the plurality of normal bonding areas from one combination unit and a corresponding one of the plurality of normal bonding areas from an adjacent combination unit and adjacent to the each of the plurality of normal bonding areas in the first direction is shorter than a fourth distance between two adjacent normal bonding areas of the same combination unit.

12. The display panel according to claim 7, wherein four combination units adjacent to each other in the first direction and the second direction constitute the repeating unit, and the normal bonding areas and the redundant bonding areas in the same row in the second direction of the repeating unit are arranged alternately.

13. The display panel according to claim 1, wherein the plurality of normal bonding areas and the plurality of redundant bonding areas are arranged in an array along a first direction and a second direction, and the first direction and the second direction are intersected with each other;
a plurality of adjacent sub-pixels constitute a pixel unit, and a plurality of bonding groups electrically connected to the pixel unit constitute a combination unit; the normal bonding area and the redundant bonding area of the same bonding group are arranged along the first direction, the plurality of normal bonding areas of the combination unit are adjacently arranged in the same row along the second direction, and the plurality of redundant bonding areas of the combination unit are adjacently arranged in the same row along the second direction;
a row of redundant bonding areas is provided between a row of the normal bonding areas of one combination unit and another row of the normal bonding areas of an adjacent combination unit in at least one of the first direction and the second direction.

14. The display panel according to claim 13, wherein a number of adjacent pixel units in an oblique direction is greater than a number of adjacent pixel units arranged in the same row in a first direction or a second direction, the oblique direction is intersected with the first direction and the second direction, and all the sub-pixels in each pixel unit of two adjacent pixel units are arranged in the same row.

15. The display panel according to claim 1, wherein the driving backplane further comprises a plurality of pixel driving circuits, and the normal bonding areas and the redundant bonding areas of the same bonding group are electrically connected to the same pixel driving circuit.

16. The display panel according to claim 15, wherein a side of each sub-pixel facing the first surface is provided with a first electrode and a second electrode, each normal bonding area or redundant bonding area comprises a first electrode bonding area configured to be electrically connected to the first electrode and a second electrode bonding area configured to be electrically connected to the second electrode, and two first electrode bonding areas of the same bonding group are electrically connected to an output terminal of the same pixel driving circuit.

17. The display panel according to claim 16, wherein the plurality of normal bonding areas and the plurality of redundant bonding areas are arranged in an array along a first direction and a second direction, the first direction and the second direction are intersected with each other; the second electrode bonding areas of all the normal bonding areas and the redundant bonding areas in the same row in the second direction are arranged on the same straight line, and all the second electrode bonding areas on the same straight line are electrically connected to a same power supply voltage line.

18. The display panel according to claim 17, wherein the power supply voltage line is arranged between two rows of the second electrode bonding areas arranged in the first direction, and the power supply voltage line is electrically connected to the two rows of the second electrode bonding areas adjacent to the power supply voltage line.

19. The display panel according to claim 16, wherein two first electrode bonding areas of the same bonding group face each other and are arranged at intervals in the first direction, the two first electrode bonding areas of the same bonding group are arranged between two second electrode bonding areas of the same bonding group, and an orthographic projection of the output terminal of the pixel driving circuit projected on the first surface in the first direction is located between the two first electrode bonding areas; or
the two first electrode bonding areas of the same bonding group face each other and are arranged at intervals in the second direction, the two second electrode bonding areas of the same bonding group face each other and are arranged at intervals in the second direction; and a gap is defined between two rows of the bonding groups of the same combination unit arranged in the first direction, and the orthographic projection of the output terminal of the pixel driving circuit projected on the first surface in the first direction is located in the gap and between the two first electrode bonding areas of the same bonding group.

20. A preparation method of a display panel according to claim 1, comprising:
providing a driving backplane; wherein, a first surface of the driving backplane is provided with a plurality of normal bonding areas and a plurality of redundant bonding areas; a distance between every two of the plurality of normal bonding areas adjacent to each other is defined as a first distance; a distance between each of the plurality of normal bonding areas and a corresponding one of the redundant bonding areas which is adjacent to the each of the plurality of normal bonding areas is defined as a second distance, and at least one of the first distances is greater than at least one of the second distances; and at least one of the plurality of normal bonding areas and at least one of the plurality of redundant bonding areas adjacent to the at least one of the plurality of normal bonding areas constitute a bonding group;
disposing a plurality of sub-pixels in the normal bonding areas of the driving backplane; and
introducing a patched sub-pixel with the same emitting color as a defective sub-pixel in the redundant bonding area, in response to the sub-pixel bonded to the normal bonding area of the same bonding group being determined to be the defective sub-pixel.
